(19) United States
(12) Patent Application Publication
(10) Pub. No.: US 2025/0235961 A1
(43) Pub. Date: Jul. 24, 2025

(54) Apparatus and Method for Establishing a Contact Connection

(71) Applicant: Pac Tech - Packaging Technologies GmbH, Nauen (DE)

(72) Inventors: Matthias Fettke, Berlin (DE); Andrej Kolbasow, Paulinenaue (DE); Svetlana Milz, Berlin (DE)

(21) Appl. No.: 18/700,167

(22) PCT Filed: Jun. 14, 2023
(86) PCT No.: PCT/EP2023/065900

§ 371 Date: Apr. 10, 2024

(30) Foreign Application Priority Data
Jun. 28, 2022 (DE) 10 2022 116 028.9

(51) Int. Cl. B23K 26/70; B23K 1/005; H01L 23/00

(52) U.S. Cl. CPC B23K 26/702; B23K 1/0056; H01L 24/75; H01L 24/81; H01L 2224/75262; H01L 2224/81224; H01L 2924/401

(57) ABSTRACT

An apparatus and method for establishing a contact connection between at least one connection contact of a substrate and at least one connection contact of a semiconductor component, a conductor material web being formed on the substrate and the semiconductor component. The apparatus includes a joining tool for positioning and joining the semiconductor component on/to the substrate, a beam channel for optical radiation being formed within the joining tool, a laser device for applying laser radiation to the substrate and/or to the semiconductor component, a detection device for detecting optical radiation, and a substrate receptacle on which the substrate is fixed in place and with which at least one underside of the substrate can be brought into contact. An optical window having an optically transparent window body is incorporated in the substrate receptacle for the unobstructed passage of optical radiation into and/or out of the substrate, the optical window being disposed in a beam path of the laser device and/or in a beam path of the detection device.

### CROSS-REFERENCE TO RELATED APPLICATION

This application represents the U.S. national stage entry of International Application No. PCT/EP2023/065900 filed Jun. 14, 2023, which claims priority to German Patent Application No. 10 2022 116 028.9 filed Jun. 28, 2022, the disclosure of which is incorporated herein by reference in its entirety for all purposes.

### TECHNICAL FIELD

The disclosure relates to an apparatus and a method for establishing a contact connection between at least one connection contact of a substrate and at least one connection contact of a semiconductor component having a joining tool, a laser device and a detection device.

### BACKGROUND

Soldering semiconductor components, in particular chips, onto a substrate, which can be a circuit board, for example, by means of a laser soldering system is well-known from the state of the art. To this end, connection contacts of the chip or of the semiconductor component are connected to a solderable connection contact of the substrate via a solder material. The solderable connection contact can be provided with the solder, for example, by means of a solder ball supply device of the laser soldering system, and the solder can be at least partly melted by means of a laser device in such a manner that a substance-to-substance bond can be created between the connection contacts of the chip or of the semiconductor component and the connection contact of the substrate. By heating the chip or the semiconductor component and/or the substrate, a connection contact disposed on the chip or on the substrate can also be at least partly melted in order to create a substance-to-substance bond between the connection contacts of the chip or of the semiconductor component and the connection contact of the substrate after the chip or the semiconductor component has been applied to the substrate.

Additionally, in a plurality of the known methods for applying a semiconductor component to a substrate, such as the methods referred to as the Chip-on-Wafer method or the Chip-on-Board method, the substrate is always larger than the semiconductor component to be placed. Rotating the substrate in order to protect temperature-sensitive components is generally not possible or extremely complicated.

It is known from the state of the art to position the substrate on a substrate receptacle and to introduce the thermal energy required for producing the substance-to-substance bond via the upper side of the substrate and/or via a joining tool, which serves to position and join the semiconductor component on/to the substrate. Because of the thermal energy being introduced only via the upper side of the substrate, in particular temperature-sensitive substrates could be subject to unintended burns. From the state of the art, it is thus known for laser welding processes, for example, in which burns of the type described above can generally also occur, to provide a detection device for monitoring, in particular with the aim to determine whether or not a burn has occurred during the laser welding process on the basis of optical radiation. The optical radiation can be detected by an infrared camera, for example. However, for devices known from the state of the art for establishing a contact connection in which the laser radiation is applied to an upper side of the substrate, it is disadvantageous or not possible to additionally detect an optical radiation because an offset between the detection devices disposed above the substrate, in particular a camera, and the laser devices must always be taken into consideration and configured. Additionally, based on the limited space above the substrate, it can be disadvantageously required that the laser device and the detection device must be moved while the contact connection is being established in order to release a beam channel, for example. Due to the vertical movement of the mentioned components, this can cause positioning errors relative to the substrate.

### SUMMARY

It is therefore the object of the present disclosure to propose an apparatus for establishing a contact connection by means of which a reliable and cost-effective monitoring and application of the required laser radiation can be carried out while preventing damage to the substrate and preventing positioning errors.

This object is attained by an apparatus having the features disclosed herein and by a method having the features disclosed herein.

The apparatus according to the disclosure serves to establish a contact connection between at least one connection contact of a substrate and at least one connection contact of a semiconductor component, a conductor material web being formed on the substrate and the apparatus comprising a joining tool for positioning and joining the semiconductor component on/to the substrate, a beam channel for optical radiation being formed within the joining tool, and the apparatus further comprising a laser device for applying laser radiation to the substrate and/or to the semiconductor component, and the apparatus further comprising a detection device for detecting optical radiation. Additionally, the apparatus according to the disclosure comprises a substrate receptacle on which the substrate can be fixed in place and with which at least one underside of the substrate can be brought into contact, an optical window having an optically transparent window body being incorporated in the substrate receptacle for the unobstructed passage of optical radiation into and/or out of the substrate, the optical window being disposed in a beam path of the laser device or of the detection device.

Preferably, the semiconductor component is a chip. The substrate is preferably a non-conducting substrate and has a conductor material web formed on the substrate. It is conceivable that the semiconductor component to be connected to the substrate is not a chip, but another substrate having a conductor path. In the context of this disclosure, the semiconductor component and the substrate are also referred to as joining partners, since they are joined for establishing a contact connection. In the context of this disclosure, the term “joining process” refers to the positioning of the joining partners to each other, the heating of at least one joining partner and the applying of one joining partner to the other, for example at a predetermined contact pressure.

The chips can have a housing or can be formed as a semiconductor component without a housing and can be disposed directly on a substrate. Direct contact can be established between the connection contacts of the chip and the conductor material web of the substrate.

The substrate can be made of a plastic or ceramic material, substrate conductor material webs for connecting electronic semiconductor components preferably being formed first. Forming the conductor material webs on the substrate can be effected according to a method well known from the state of the art.

The term “laser device” can be understood to mean a laser emitter for emitting laser radiation on its own or also a laser emitter in combination with a radiation transmitting device, by means of which the laser radiation is transmitted from the laser emitter to the substrate. Devices comprising lenses and/or reflectors are known as radiation transmitting devices.

In the context of this disclosure, the term “underside of the substrate” refers to the side of the substrate which comes into contact with the substrate receptacle and which faces away from the semiconductor component. Accordingly, the connection contacts on the upper side of the substrate opposite the underside are formed for being connected to the connection contacts of the semiconductor component.

In this case, the term “optical radiation” is not limited to light visible to the naked eye, instead, it can rather comprise the entire electromagnetic spectrum, in particular also infrared radiation (thermal radiation) and ultraviolet radiation. The natural source of optical radiation is the sun, however, optical radiation can also be generated artificially.

In the context of this disclosure, the term “optical window” refers to optically transparent plates, which are typically designed such that they provide a maximum transmission of optical radiation within a certain wavelength range and also reduce reflection and absorption. Additionally, the optical window acts as a thermal insulator, such that the largest amount of heat possible can be transmitted through the optical window.

The fundamental concept of this disclosure is that the apparatus has, in addition to a beam channel for applying optical radiation to the upper side of a substrate or to a semiconductor component to be disposed on the upper side of a substrate, an optical window in the substrate receptacle. By means of the optical window, additional optical radiation can be introduced into the substrate, in particular into the underside of the substrate, and/or optical radiation can be reflected and detected by the optical window. This makes it possible to introduce the thermal energy required for establishing a contact connection either via the underside of the substrate, i.e., from below in relation to the substrate, or through the beam channel of the joining tool, i.e., from above in relation to the substrate. In particular if the laser radiation for introducing the necessary thermal energy is introduced into the substrate through the optical window, the semiconductor component to be disposed on the substrate can be positioned without taking the laser device into account, as the joining tool and the detection device have considerably more space available above the substrate due to the application of the laser radiation from below. This also minimizes the travel paths necessary when changing or aligning the joining tool, the laser device and the detection device above the substrate, for example, thus preventing positional deviations during the joining process. In addition, it is possible to carry out a direct and active position adjustment during the joining process of the apparatus according to this disclosure, since different optical radiations can be applied or detected simultaneously through the two optical radiation accesses, namely the beam channel in the joining tool and the optical window in the substrate receptacle. It is thus possible to simultaneously introduce the laser radiation for applying the thermal energy through a beam path into the substrate and simultaneously detect an optical radiation through the second beam path by means of the detection device and use this to determine the position of the substrate relative to the substrate receptacle or of the semiconductor component relative to the substrate. Thus, it is advantageously possible to apply laser radiation already during the positioning of the semiconductor component on the substrate by means of the joining tool and to simultaneously use the position of the semiconductor component relative to the substrate to control the positioning tool, said position being determined by the detection device.

In the context of this disclosure, the detection device acts in particular as a device for detecting optical radiation, by means of which the joining process for establishing a contact connection, in particular the focusing of the laser radiation on the connection contacts and the heating of the substrate, and also the positioning of the semiconductor component on the substrate can be monitored. This is preferably effected on the basis of the optical radiation emitted by the substrate or the semiconductor component.

By means of the apparatus for establishing a contact connection according to this disclosure, a semiconductor component can be positioned on a substrate by means of the joining tool and can be attached to the substrate, the required thermal energy being applied to the substrate and/or to the semiconductor component by means of the laser device. Preferably, the laser radiation is applied to the substrate and/or to the semiconductor component in such a way that the connection contacts of the substrate and/or of the semiconductor component are at least partly melted and, by applying the connection contacts of the semiconductor component to the connection contacts of the substrate, a substance-to-substance bond is created between the connection contacts of the substrate and the connection contacts of the semiconductor component. It is also conceivable that a solder material deposit, which is disposed between the connection contacts of the substrate and the connection contacts of the semiconductor component, is melted by the laser radiation applied by the laser device in order to create a substance-to-substance bond between the connection contacts of the substrate and the connection contacts of the semiconductor component. It is also conceivable that the connection contacts or a solder material deposit are directly exposed to laser radiation in order to introduce the required thermal energy, or that the thermal energy is introduced into the substrate and/or into the semiconductor component by means of laser radiation and is transferred to the connection contacts of the substrate or the semiconductor component.

In order to eliminate errors during the production of the contact connection, in particular during the joining of the semiconductor component to the substrate, the detection device is designed in such a manner that it can detect the position of the semiconductor component relative to the substrate by means of a, preferably reflected, optical radiation and can also monitor the process parameters of the joining process, in particular the temperature of the substrate and of the semiconductor component, by means of a reflected optical radiation. In order to simplify the positioning of the semiconductor component relative to the substrate, the apparatus according to this disclosure has a substrate receptacle on which the substrate can be fixed in place. Preferably, the substrate is form-fittingly mounted on the substrate receptacle so that the underside of the substrate rests on the substrate receptacle and on the optical window and at least partially covers the optical window. It is also conceivable that the substrate is mounted on the substrate receptacle by generating a holding force. To generate the holding force, a negative pressure can be applied to the substrate resting on the substrate receptacle. The substrate receptacle thus allows a positioning fixation of the substrate and simultaneously allows an unobstructed passage of optical radiation into and/or out of the substrate because of the optical window. In summary, the apparatus according to this disclosure can advantageously be used to simultaneously subject the substrate and/or the semiconductor component to laser radiation and to detect optical radiation for monitoring the positioning of the joining partners and the joining process via beam paths which end on the substrate and/or on the semiconductor component and hit the substrate or the semiconductor component from different directions.

Advantageous embodiments of the invention are subject matter of the dependent claims. The invention also relates to all combinations comprising at least two features disclosed in the description, the claims and/or the figures. It is understood that all features and embodiments disclosed in the context of the apparatus also relate in an equivalent, albeit not identical, manner to the method according to the invention. In particular, linguistically common rephrasing and/or an analogous replacement of respective terms within the scope of common linguistic practice, in particular the use of synonyms backed by the generally recognized linguistic literature, are of course comprised by the content of the disclosure at hand without every variation having to be expressly mentioned.

It has proven to be advantageous if the detection device comprises an infrared sensor unit and/or an image capturing unit. The image capturing unit is preferably a camera. An infrared sensor unit, which can preferably contactlessly measure the temperature of the semiconductor component and/or of the substrate based on the reflected radiation, is preferably used for measuring the temperature. It is also conceivable that an infrared sensor unit for detecting the position of the substrate is used if fiducial markers whose infrared radiation can be distinguished from the infrared radiation of the substrate are disposed on the substrate. By detecting optical radiation in the infrared range within a wavelength range of 780 nm and 1 mm, the infrared sensor unit can be used for detecting the position of the semiconductor component and/or of the substrate as well as for monitoring the process parameters of the joining process, in particular for monitoring the temperature of the joining partners, meaning the semiconductor component and the substrate. The image capturing unit is preferably used for positioning the semiconductor component relative to the substrate and/or for positioning the substrate relative to the substrate receptacle.

It is also conceivable that the apparatus, in particular the detection device, has a processing unit. The processing unit preferably has at least one processor and/or a volatile and/or non-volatile memory and is configured to continue to process the position data and/or process data, in particular temperature values, detected by the infrared sensor unit and/or the image capturing unit and is configured to control the joining tool and/or the laser device in accordance with the detected values. This means that the processing unit can react directly to positional deviations, for example, by controlling the joining tool in order to correct the position of a semiconductor component relative to the substrate. It is also conceivable that the processing unit of the detection device controls the laser device on the basis of the temperature values recorded by the detection device in order to correct the intensity of the laser radiation and thus the energy input. It is also conceivable that the processing unit emits an acoustic and/or visual signal, for example, if the real (actual) position deviates from the desired (target) position or if a predefined temperature limit in the semiconductor component or in the substrate is exceeded. The operator can then manually stop operation of the apparatus and/or make corrections if necessary. Operation of the apparatus can also be stopped automatically during the joining process in the event of the aforementioned deviations in order to prevent damage to the substrate, the semiconductor component and/or the apparatus.

According to a preferred embodiment, the optical window is disposed in a beam path of the laser device and the beam channel of the joining tool is disposed in the beam path of the infrared sensor unit. In other words, the laser device and the infrared sensor unit are disposed such that the beam path of the laser device passes through the optical window and the beam path of the infrared sensor unit passes through the beam channel of the joining tool. The arrangement according to this design offers the advantage that the substrate can be exposed to laser radiation from below through the optical window and, at the same time, the infrared radiation reflected by the semiconductor component and/or by the substrate can be detected by the beam channel of the joining tool. In this way, the temperature of the joining partners and the positioning of the joining partner can be easily monitored by means of the infrared sensor unit and, at the same time, energy can be introduced into the substrate in order to create a substance-to-substance bond between the joining partners by melting the connection contacts.

According to another embodiment, the optical window is disposed in a beam path of the infrared sensor unit and the beam channel of the joining tool is disposed in the beam path of the laser device. This means that the infrared sensor unit and the laser device are disposed such that the beam path of the infrared sensor unit passes through the optical window and the beam path of the laser device passes through the beam channel of the joining tool. This embodiment is advantageous in that infrared radiation and laser radiation can be detected and applied simultaneously without the laser device and the infrared sensor unit affecting each other and/or having to be displaced because of lack of space.

According to a third embodiment, the optical window is disposed in a beam path of the image capturing unit and the beam channel of the joining tool is disposed in the beam path of the laser device and the infrared sensor unit, such that a beam path of the laser source and a beam path of the infrared sensor unit simultaneously pass through at least sections of the beam channel. In other words, the image capturing unit, the infrared sensor unit and the laser device are disposed such that the beam path of the image capturing unit passes through the optical window and the beam path of the laser device and the infrared sensor unit passes through the beam channel of the joining tool. According to this embodiment, the position of the substrate relative to the substrate receptacle and the position of the semiconductor component relative to the substrate can advantageously be detected from below by the image capturing unit and, in addition, the substrate and/or the semiconductor component can be subjected to laser radiation from above and, simultaneously, the infrared radiation of the infrared sensor unit reflected by the semiconductor component and/or the substrate can be detected to monitor the temperature of the semiconductor component and/or the temperature of the substrate. Combining the image capturing unit, the infrared sensor unit and the laser device increases the safety of the process control, as the position measurement can be carried out using both the image capturing unit and the infrared sensor unit. Preferably, the position measurement is carried out by means of the image capturing unit and a temperature measurement is carried out by means of the infrared sensor unit.

It is also conceivable that the image capturing unit and the infrared sensor unit are disposed above the substrate and the substrate receptacle and the beam path of the image capturing unit and the beam path of the infrared sensor unit thus pass through the beam channel of the joining tool, while the application of laser radiation by means of the laser device relative to the substrate receptacle is effected through the optical window from below.

Furthermore, it has proven to be advantageous if the laser device and/or the detection device and/or the substrate receptacle is/are disposed on a table capable of being displaced along at least two axes. Preferably, the laser device or the substrate receptacle is disposed on a table capable of being displaced along at least two axes. The displaceability of the laser device and/or of the detection device and/or of the substrate receptacle by means of a table capable of being displaced along at least two axes advantageously allows a relatively large substrate to be connected either to a relatively large semiconductor component or to several semiconductor components. In particular, this might be required if the energy input or the focusing of the laser beam emitted by the laser device is not sufficient for simultaneously heating all required connection contacts for establishing a contact connection. In the event of such requirements, the laser device and the substrate can be displaced relative to each other by means of the table capable of being displaced along two axes. In particular, it is conceivable that the laser device is moved from a first connection contact of the substrate or a first connection contact group of the substrate to another connection contact or another connection contact group by means of the table capable of being displaced along two axes, a connection contact group comprising several connection contacts which can be heated by the laser in one step, that the laser device is positioned at the corresponding position and that energy is introduced into the substrate by means of laser radiation. Preferably, the tool table can be displaced along two axes in the X-Y plane, the X-Y plane being disposed parallel to the supporting surface of the substrate receptacle. However, it is also conceivable that the tool able is also displaceable perpendicular to this X-Y plane, i.e., in the Z direction of a Cartesian coordinate system, for example, to change the focus of the detection device or of the laser device disposed on the tool table. More preferably, the tool table is disposed below the substrate receptacle in order to be able to displace the substrate receptacle and/or the laser device and/or the detection device without impairing the processes taking place above the substrate receptacle.

According to a preferred embodiment, a base plate and a base for distancing the substrate receptacle from the base plate are comprised. To introduce an optical radiation into the substrate or to detect an optical radiation emerging from the substrate, it is necessary that the optical window is accessible for the beam path of the laser device and/or of the detection device. It has proven advantageous, in particular to forego complex deflection units for guiding the optical radiation through the optical window, to dispose the laser device and/or the detection device below the substrate receptacle. In order to provide the required space and at the same time keep the accuracy and stability of the device as high as required, it has proven to be advantageous to dispose the substrate receptacle on at least one base, preferably two or four bases, and to connect these bases to a base plate which is parallel to the substrate receptacle. Thus, it is possible to dispose the detection device and/or the laser device between the substrate receptacle and the base plate. It is possible to fix the laser device and/or the detection device in place relative to the substrate and the base plate, or to dispose the detection device and/or the laser device on a displaceable table and thus variably displaceable between the base plate and the substrate receptacle. It is also conceivable to realize a displaceable substrate receptacle by disposing the at least one base on a tool table that can be displaced along two axes.

According to another preferred embodiment, the optical window lines up flush with the substrate receptacle on at least one side and forms a shared flat surface with the substrate receptacle, said shared flat surface being brought into contact with the underside of the substrate. In other words, this means that the optical window is incorporated in the substrate receptacle in such a manner that the sides of the substrate receptacle and the optical window facing the substrate form a shared flat surface on which the substrate can rest. This advantageously creates the largest possible supporting surface for the substrate, which simplifies positioning and increases repeat accuracy. It is conceivable that the optical window is flush with the substrate receptacle on two sides, namely on the upper side of the substrate receptacle, which faces the substrate, and on the opposite underside of the substrate receptacle. In other words, this means that the substrate receptacle and the optical window can have the same thickness.

In order to allow the optical radiation to pass through the optical window as unobstructedly as possible, it has proven to be advantageous for the window to be made of glass and/or to have an anti-reflection coating. Preferably, the optical window is made of glass and has an anti-reflection coating. More preferably, the optical window has an anti-reflection coating on the side facing the laser device, i.e., on the side on which the laser radiation hits the optical window. Even more preferably, the upper side of the optical window facing the substrate and the underside of the optical window opposite the upper side have an anti-reflection coating. The anti-reflection coating can advantageously prevent back reflections of optical radiation, for example laser radiation, so that the energy of the laser radiation can be almost completely introduced into the substrate or the semiconductor component.

In a second aspect, this disclosure relates to a method for establishing a contact connection between at least one connection contact of a conductor material web and at least one connection contact of a semiconductor component, in particular a chip, the conductor material web being formed on a non-conducting substrate, and the method comprising at least the following steps:

Fixing a substrate in place on a substrate receptacle, such that an underside of the substrate is brought into contact with the substrate receptacle;

Positioning a semiconductor component on the substrate by means of a joining tool;

Subjecting the substrate and/or the semiconductor component to laser radiation in order to at least partly melt the connection contacts and for creating a substance-to-substance bond between the connection contacts of the conductor material web and the semiconductor component;

Detecting an optical radiation by means of a detection device for detecting the position of the substrate and/or for detecting the position of the semiconductor component and/or for measuring the temperature of the substrate and/or for measuring the temperature of the semiconductor component.

It is essential to this disclosure that at least one beam path of an optical radiation is guided into and/or out of the substrate through a window having an optically transparent window body, said window being inserted in the substrate receptacle, and that a beam path of another optical radiation is guided through a beam channel formed within the joining tool. Preferably, the temperature of the connection contacts of the substrate and/or of the semiconductor component is measured on the basis of the detected optical radiation. To create a substance-to-substance bond between the connection contacts of the conductor material web and the semiconductor component, it is conceivable that, after the connection contacts have been subjected to laser radiation or while the connection contacts are being subjected to laser radiation, which causes the connection contacts to at least partly melt, the joining tool applies a force to the semiconductor component, such that a contact pressure is transmitted to the connection contacts of the joining partners forming the contact pair. On the other hand, it is also conceivable that the semiconductor component and the substrate are only in contact with each other due to the weight of the semiconductor component. In the method according to this disclosure, the application of laser energy and the monitoring of the joining process is carried out in deviation from known methods by forming different beam paths, a beam path being guided through a window incorporated in the substrate receptacle, and therefore the substrate being advantageously accessible to radiation from two sides.

According to a preferred embodiment of the method, at least one fiducial marker disposed on the substrate and/or on the semiconductor component is detected by the detection device and the substrate, the semiconductor component and/or the beam path of the optical radiation are aligned on the basis of the detected fiducial marker. In the context of this disclosure, fiducial markers refer to any markings on the substrate or on the semiconductor component that can be used to position the substrate or the semiconductor component. Fiducial markers are generally optical reference points that can be used to position the substrate on the substrate receptacle and to position the laser device, the detection device and/or the semiconductor component relative to the substrate. In addition to the positioning of the substrate, the fiducial markers can also be used to determine the size of the substrate. Preferably, the fiducial markers are captured using an image capturing unit. The fiducial markers are recorded, and subsequently, preferably by means of a processing unit, the position of one or several fiducial markers can be compared with an image of the printed circuit board stored in the processing unit, and any elongation, compression or twisting of the printed circuit board can be compensated.

It has proven to be advantageous, in particular if an infrared sensor unit is used for measuring the temperature of the substrate and/or of the semiconductor component, to detect the at least one fiducial marker by means of an infrared sensor unit on the basis of the infrared radiation reflected by the at least one fiducial marker when subjected to heat. This means that at least one fiducial marker can also be detected with little effort, in particular if an infrared sensor unit is already provided for temperature measurement. The fiducial marker preferably has metallic structures whose reflected infrared radiation differs from the non-conducting substrate of the conductor material web.

According to another preferred embodiment of the method, a measurement of the temperature of the connection contacts of the substrate and/or of the semiconductor component is carried out by means of an infrared sensor unit by measuring the infrared radiation reflected from a reference surface of the connection contacts. It has proven to be advantageous to directly measure the temperature of the connection contacts, which are to be at least partly melted for producing a connection, in order to determine the temperature of the connection contacts as accurately as possible and to be able to adjust the temperature curve or energy input as directly as possible.

Furthermore, it is conceivable that the semiconductor component is applied to an at least partly transparent substrate or to a conductor material web, which is formed on an at least partly transparent substrate. In the context of this disclosure, a transparent substrate is an optically transparent substrate configured to provide maximum transmission of optical radiation in a given wavelength range while reducing reflection and absorption. Preferably, the substrate is transparent in the area of the fiducial markers for detecting the fiducial markers by means of the detection device. Thus, for example, the detection of the fiducial markers can be carried out through the optical window and the substrate. This allows the fiducial markers to be detected from the underside or the upper side of the substrate in a simple and flexible manner.

According to another preferred embodiment of the method, the laser device and/or the detection device are displaced along at least two axes, in particular below the optical window, for being aligned relative to the substrate. This enables a plurality of semiconductor components and/or a relatively large semiconductor component to be attached to a relatively large substrate in a simple manner. Preferably, the laser device is displaced below the substrate receptacle and the optical window along two axes relative to the substrate or the substrate receptacle. However, it is also conceivable that the substrate receptacle is disposed on a table that can be moved along at least two axes for positioning the substrate and that the substrate receptacle is displaced relative to the detection device and/or the laser device.

It is obvious that the embodiments and the illustrative examples described above and yet to be explained below can be implemented not only individually but also in any combination without departing from the scope of the present invention. It is also obvious that the embodiments and the illustrative examples described above and yet to be explained below relate to the method according to the invention in an equivalent or at least in a similar manner without having to be mentioned separately.

### BRIEF DESCRIPTION OF THE FIGURES

Embodiments are schematically illustrated in the drawings and are described in an exemplary manner hereinafter.

FIG. 1 shows a first schematic illustrative example of an apparatus according to this disclosure.

FIG. 2 shows a second schematic illustrative example of an apparatus according to this disclosure.

FIG. 3 shows a third schematic illustrative example of an apparatus according to this disclosure.

FIG. 4 shows a fourth schematic illustrative example of an apparatus according to this disclosure.

### DETAILED DESCRIPTION

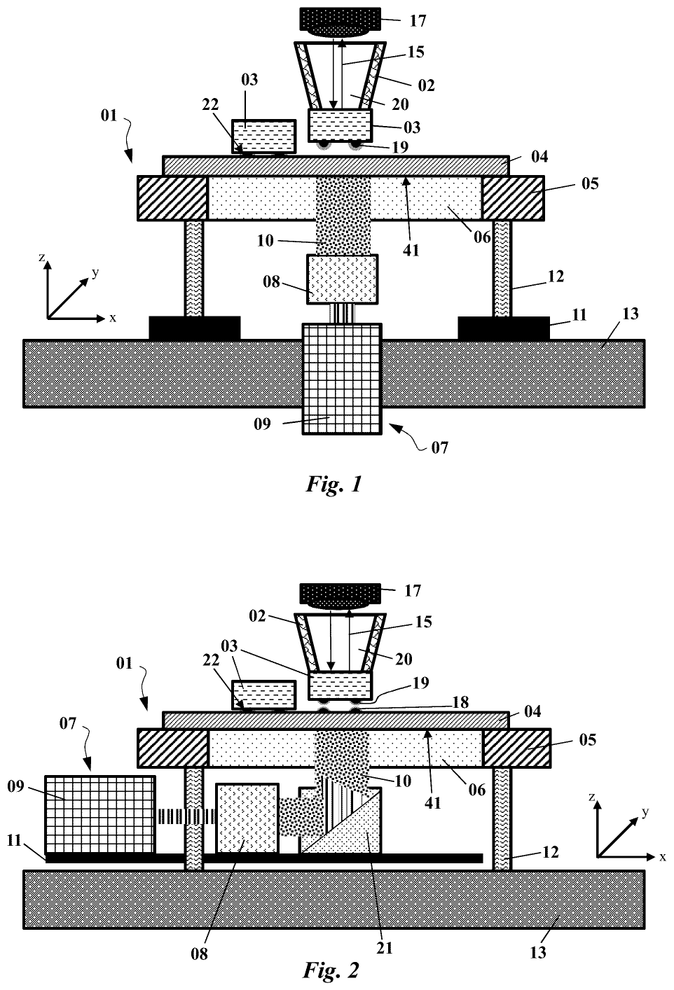

FIGS. 1 and 2 both show an embodiment of the apparatus according to this disclosure for establishing a contact connection 22 between at least one connection contact 18 of a substrate 04 and at least one connection contact 19 of a semiconductor component 03, semiconductor component 03 being a chip. It can be seen in FIGS. 1 and 2 that an optical window 06, which allows the rearward application of optical radiation to substrate 04, is incorporated in substrate receptacle 05. Laser radiation is applied to underside 41 of substrate 04 by means of laser device 07, which, in addition to laser emitter 09, comprises a lens system 08. Beam path 10 of laser device 07 passes through optical window 06 onto underside 41 of substrate 04. According to the embodiments shown in FIGS. 1 and 2, semiconductor component 03 and in particular connection contacts 19 of semiconductor component 03 can be subjected to laser radiation through optical window 06 and substrate 04 and can be at least partly melted by means of the energy input of the laser radiation. It is conceivable that the substrate is transparent for this purpose. By means of joining tool 02, semiconductor component 03 can be positioned and disposed on substrate 04. After semiconductor component 03 has been applied to substrate 04, at least partly melted connection contacts 19 create a contact connection 22 between semiconductor component 03 and substrate 04, preferably a conductor material web (not shown) formed on substrate 04. For measuring the temperature of semiconductor component 03 and/or for detecting the position of semiconductor component 03 relative to substrate 04, an infrared sensor unit 17 is disposed above substrate 04, beam path 15 of infrared sensor unit 17 passing through beam channel 20 formed within joining tool 02. As can be seen in FIGS. 1 and 2, the reflected radiation reflected by semiconductor component 03 and passing through beam channel 20 is detected by infrared sensor unit 17 and is evaluated to determine the temperature and/or position. Furthermore, the embodiments according to FIGS. 1 and FIG. 2 of apparatus 01 for establishing a contact connection 22 have a tool table 11 displaceable in the X-Y direction. The travel path in the Y direction runs into the image plane, the travel path in the X direction runs perpendicular thereto, and another possible travel path in the Z direction runs perpendicular to the X and Y directions and from base plate 13 towards substrate receptacle 05. The arrangement of substrate receptacle 05 on bases 12, which connect substrate receptacle 05 to base plate 13, serves to provide the required space to be able to arrange laser device 07 below substrate receptacle 05 and optical window 06. It can also be seen from FIGS. 1 and 2 that optical window 06 is flush with the upper side of substrate receptacle 05, at least on its upper side facing substrate 04. This makes it possible to form a flat supporting surface for substrate underside 41 on the upper side of substrate receptacle 05 or of optical window 06.

The first illustrative example according to FIG. 1 and the second illustrative example according to FIG. 2 of the apparatus according to this disclosure essentially differ in the different arrangement of tool table 11 and laser device 07. In the first illustrative example, which is shown in FIG. 1, bases 12 are disposed on tool table 11, whereby substrate receptacle 05 is displaceable in the X-Y direction by means of tool table 11. This makes it easy to position substrate 04 relative to laser device 07 and joining tool 02 and thus also to semiconductor component 03. Furthermore, laser device 07 of the first illustrative example of the apparatus according to this disclosure has a laser emitter 09 and a lens system 08, lens system 08 and laser emitter 09 being disposed below optical window 06 or substrate 04 such that a deflection of laser radiation is not required and thus beam path 10 hits substrate underside 41 directly, without being deflected, or beam path 10 hits semiconductor component 03 directly after passing through substrate 04.

In contrast, laser device 07 according to the second illustrative example shown in FIG. 2 has, in addition to laser emitter 09 and lens system 08, a deflection mirror 21, which deflects the laser radiation after passing through lens system 08 and thus directs it onto substrate 04. Thus, beam path 10 of the laser radiation first runs in the X direction, starting from laser emitter 09, up to deflection mirror 21, and from there the beam path continues in the Z direction towards substrate 04. It can also be seen from FIG. 2 that, according to the second illustrative example, laser device 07 is disposed on tool table 11 and can thus be moved in the X-Y direction. Thus, according to the second illustrative example, laser device 07 can be positioned relative to substrate 04 in a simple manner.

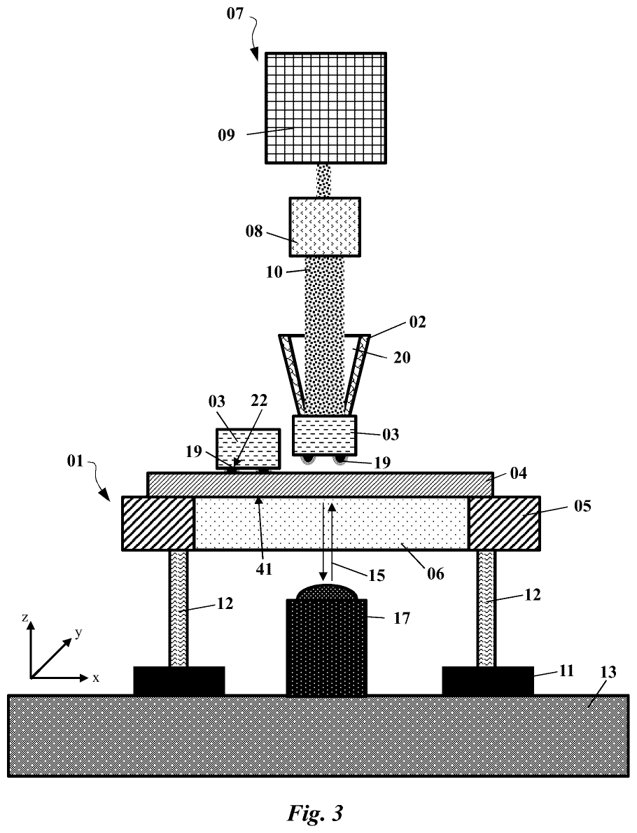

FIG. 3 shows a third illustrative example of the apparatus according to this disclosure. Laser device 07 is disposed in the Z direction above substrate 04 and in such a way that beam path 10 of laser device 07 passes through beam channel 20 of joining tool 02. Laser device 07 has a laser emitter 09 for emitting a laser radiation and a lens system 08 for beam widening or beam focusing. It can be seen in FIG. 3 that a semiconductor component 03 is already connected to substrate 04 via two connection contacts 19 or is conductively connected to a conductor material web (not shown) formed on substrate 04. Another semiconductor component 03 is held by joining tool 02, for example by a negative pressure, and can be positioned on substrate 04 by means of joining tool 02. For at least partly melting connection contacts 19, semiconductor component 03 held on joining tool 02 is exposed to laser radiation from above through beam channel 20. The joining process, in particular the melting of connection contacts 19, is monitored by infrared sensor unit 17. Infrared sensor unit 17 detects an infrared radiation reflected from substrate 04 and/or semiconductor component 03 to detect the temperature and/or the position of semiconductor 03 relative to substrate 04. In addition, infrared sensor unit 17 can recognize the fiducial marker (not shown) arranged on substrate 04 on the basis of its reflected radiation and can thus also monitor the correct positioning of substrate 04 relative to substrate receptacle 05 and/or relative to joining tool 02 or semiconductor component 03 held thereon. According to the third illustrative example, infrared sensor unit 17 is disposed below substrate receptacle 05, whereby beam path 15 of infrared sensor unit 17 passes through optical window 06 towards substrate 04. Disposing infrared sensor unit 17 is made possible by the fact that substrate receptacle 05 is disposed on bases 12, which distance substrate receptacle 05 from base plate 13 of apparatus 01. Optical window 06 is incorporated in substrate receptacle 05 in such a manner that substrate underside 41 can rest on the upper side of substrate receptacle 05 and on the upper side of optical window 06 in a flush manner. In order to be able to position substrate receptacle 05 and thus substrate 04 in a simple manner relative to infrared sensor unit 17 and/or joining tool 02, bases 12, on which substrate receptacle 05 is disposed, are connected to a tool table 11 which can be moved at least in the X-Y direction.

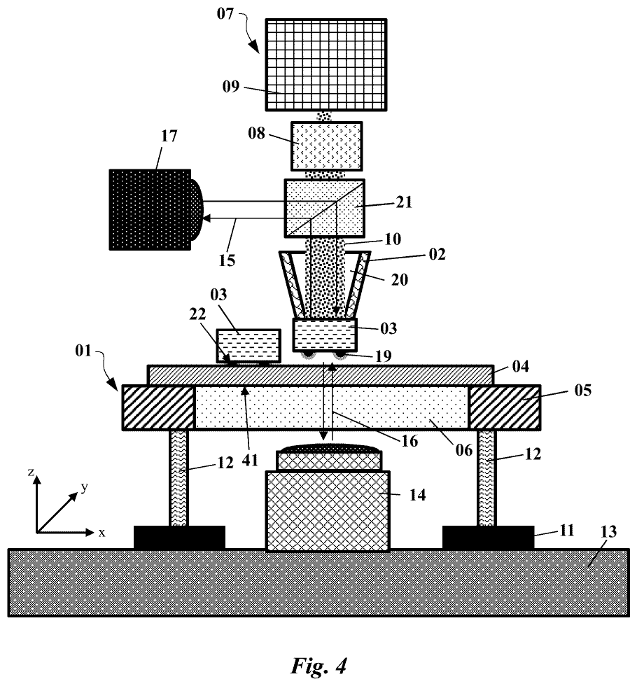

FIG. 4 shows a fourth illustrative example of apparatus 01 according to this disclosure. According to the fourth illustrative example, substrate receptacle 05 is again distanced from base plate 13 by bases 12, substrate receptacle 05 being displaceable in the X-Y direction by disposing base 12 on a tool table 11. Substrate 04 comes into contact with substrate underside 41 both on the upper side of substrate receptacle 05 and on the upper side of optical window 06 integrated in substrate receptacle 05. According to the shown fourth illustrative example, the detection device has both an infrared sensor unit 17 and an image capturing unit realized as a camera 14. Camera 14 is disposed below substrate receptacle 05 between base plate 13 and substrate receptacle 05, such that the radiation detected by camera 14 or beam path 16 of camera 14 passes through optical window 06 and transparent substrate 04. Thus, both the positioning of substrate 04 on substrate receptacle 05 and the positioning of semiconductor component 03 relative to substrate 04 can be monitored from below substrate receptacle 05 by means of camera 14. Thus, the positioning of substrate 04 can be easily monitored based on fiducial markers, which can be detected by camera 14. One semiconductor component 03 is already disposed on substrate 04 and another semiconductor component 03 is held on joining tool 02 for being positioned on substrate 04. To at least partly melt connection contacts 19 of semiconductor component 03, laser radiation is applied to semiconductor component 03, the energy input of the laser radiation into semiconductor component 03 melting connection contacts 19. For the application of laser radiation, laser device 07 has a laser emitter 09 and a lens system 08. It can be seen that beam path 10 of the laser radiation passes through beam channel 20 of joining tool 02, and thus beam channel 20 is disposed in beam path 10 of laser device 07 disposed above substrate receptacle 05. Furthermore, apparatus 01 has an infrared sensor unit 17 which, for measuring the temperature of semiconductor component 03 and/or substrate 04, detects an infrared radiation reflected by semiconductor component 03 and/or substrate 04. Infrared beam path 15 is deflected by deflection mirror 21, so that the reflected radiation hits infrared sensor unit 17, which is not arranged perpendicular above semiconductor component 03, but so as to be offset. By disposing laser device 07 and infrared sensor unit 17 above substrate 04, both beam path 15 of infrared sensor unit 17 and beam path 10 of laser device 07 simultaneously pass through at least sections of beam channel 20. Since, according to the fourth illustrative example shown in FIG. 4, the apparatus comprises a camera 14 and a detection device comprising infrared sensor unit 17, the joining process, in particular the temperature of the joining partners and the positioning of the joining partners, can be detected particularly reliably. The simultaneous use of camera 14 and infrared sensor unit 17 is made possible by the fact that at least one beam path 10, 15, 16, in this case beam path 16 of camera 14, passes through optical window 06 and the optical radiation can thus be detected below substrate receptacle 05.

1. An apparatus for establishing a contact connection between at least one connection contact of a substrate and at least one connection contact of a semiconductor component, a conductor material web being formed on the substrate and the semiconductor component,
the apparatus comprising a joining tool for positioning and joining the semiconductor component on/to the substrate, a beam channel for optical radiation being formed within the joining tool,
the apparatus comprising a laser device for applying laser radiation to the substrate and/or to the semiconductor component,
and the apparatus further comprising a detection device for detecting optical radiation,
and the apparatus further comprising a substrate receptacle on which the substrate is fixed in place and with which at least one underside of the substrate is brought into contact,
wherein
an optical window having an optically transparent window body is incorporated in the substrate receptacle for the unobstructed passage of optical radiation into and/or out of the substrate, the optical window being disposed in a beam path of the laser device and/or in a beam path of the detection device.

2. The apparatus according to claim 1,
wherein
the detection device comprises an infrared sensor unit and/or an image capturing unit.

3. The apparatus according to claim 2,
wherein
the optical window is disposed in a beam path of the laser device and the beam channel of the joining tool is disposed in the beam path of the infrared sensor unit.

4. The apparatus according to claim 2,
wherein
the optical window is disposed in a beam path of the infrared sensor unit and the beam channel of the joining tool is disposed in the beam path of the laser device.

5. The apparatus according to claim 2,
wherein
the optical window is disposed in a beam path of the image capturing unit and the beam channel of the joining tool is disposed in the beam path of the laser device and the infrared sensor unit, such that a beam path of the laser device and a beam path of the infrared sensor unit simultaneously pass through at least sections of the beam channel.

6. The apparatus according to claim 1,
wherein
the laser device and/or the detection device is/are disposed on a tool table capable of being displaced along at least two axes.

7. The apparatus according to claim 1, further comprising
a base plate and at least one base for distancing the substrate receptacle from the base plate.

8. The apparatus according to claim 1,
wherein
the optical window lines up flush with the substrate receptacle on at least one side and forms a shared flat surface with the substrate receptacle, said shared flat surface being brought into contact with the underside of the substrate.

9. The apparatus according to claim 1,
wherein
the optical window is made of glass and/or has an anti-reflection coating.

10. A method for establishing a contact connection between at least one connection contact of a conductor material web and at least one connection contact of a semiconductor component, the conductor material web being formed on a non-conducting substrate,
the substrate being fixed in place on a substrate receptacle in such a manner that an underside of the substrate is brought into contact with the substrate receptacle,
and a semiconductor component being positioned on the substrate by a joining tool, and the substrate being subjected to laser radiation in order to at least partly melt the connection contacts and in order to create a substance-to-substance bond between the connection contacts of the conductor material web and the semiconductor component,
and an optical radiation being detected by a detection device for detecting the position of the substrate and/or for detecting the position of the semiconductor component and/or for measuring the temperature of the substrate and/or for measuring the temperature of the semiconductor component,
wherein
at least one beam path of an optical radiation being guided into and/or out of the substrate through a window having an optically transparent window body, said window being inserted in the substrate receptacle, and a beam path of another optical radiation being guided through a beam channel formed within the joining tool.

11. The method according to claim 10,
wherein at least one fiducial marker disposed on the substrate and/or on the semiconductor component is detected by the detection device, and the substrate, the semiconductor component and/or beam path of the optical radiation are aligned on the basis of the at least one detected fiducial marker.

12. The method according to claim 11,
wherein the at least one fiducial marker is detected by of an infrared sensor unit on the basis of the infrared radiation reflected by the at least one fiducial marker when subjected to heat.

13. The method according to claim 10, wherein a measurement of the temperature of at least one connection contact of the substrate and/or at least one connection contact of the semiconductor component is carried out by an infrared sensor unit by measuring the infrared radiation reflected from a reference surface of the connection contacts.

14. The method according to claim 10, wherein the semiconductor component is applied to an at least partly transparent substrate and the detection of the at least one fiducial marker is carried out through the optical window and the substrate.

15. The method according to claim 10, wherein the laser device and/or the detection device are displaced along at least two axes for being aligned relative to the substrate.

16. The apparatus according to claim 1, wherein the semiconductor component is a chip.

17. The method according to claim 10, wherein the semiconductor component is a chip.

18. The method according to claim 15, wherein the laser device and/or the detection devices are below the optical window.
